(19) United States
(12) Patent Application Publication
(10) Pub. No.: US 2010/0072600 A1
(43) Pub. Date: Mar. 25, 2010

(54) FINE-PITCH OBLONG SOLDER CONNECTIONS FOR STACKING MULTI-CHIP PACKAGES

(75) Inventor: Mark A. GERBER, Lucas, TX (US)

Correspondence Address: TEXAS INSTRUMENTS INCORPORATED, P O BOX 655474, M/S 3999, DALLAS, TX, 75265, US

(73) Assignee: Texas Instrument Incorporated, Dallas, TX (US)

(21) Appl. No.: 12/487,346

(22) Filed: Jun. 18, 2009

Related U.S. Application Data
(60) Provisional application No. 61/099,024, filed on Sep. 22, 2008.

(51) Int. Cl. H01L 25/065; H01L 23/48; H01L 21/50; H01L 21/78

(52) U.S. Cl. 257/686; 257/698; 438/109; 438/110; 257/E25.013; 257/E23.011; 257/E21.499; 257/E21.599; 257/737; 257/774

(57) ABSTRACT

A semiconductor PoP device (100) includes a first device (101) with a first substrate (110) having on its first side (110a) a stack (115) of at least two chips, first contact pads (111), and a first package (116) having a height (116a) and a top surface (116b). Via holes (130) extend from the top package surface through the package height to the first contact pads; the vias have straight sidewalls and a diameter at the top surface of less than 75% of the height. The PoP further includes a second packaged device (102) with a second substrate (120) facing the top surface (116b) of the first package; substrate (120) has contact pads (121) in line with the first pads (111). Solder bodies (103) fill the vias (130) and connect the pads (121) with the respective first pads (111). In the fabrication method of first device (101), the vias (130) are opened through the complete package thickness (116a); thereafter, enough solder balls are filled into each via to insure contact with the respective solder body attached to the second package.

### FIELD OF THE INVENTION

The present invention is related in general to the field of semiconductor devices and processes and more specifically to the structure and fabrication method of vertically integrated low-profile, fine-pitch package-on-package integrated circuit assemblies having oblong solder connections.

### DESCRIPTION OF RELATED ART

A package-on-package (PoP) device in semiconductor technology is created by aligning a top device package with a bottom device package, and connecting the output terminals of the top package with the input terminals of the bottom package. The connection of terminals is achieved by reflowing the solder body attached to each output terminal to wet the respective terminal of the bottom package. In today's semiconductor products, PoP devices enjoy increasing popularity, because they promise to use component devices already developed and thus quickly available. For instance, examples for mobile multimedia applications include the three-dimensional integration of baseband integrated circuits (ICs) or application-specific circuits (ASICs) with high-performance memory. PoP devices are supposed to accept packages wherein the chip is assembled by wire bonds, as well as packages wherein the chip is assembled by flip-chip technology. Further, PoP devices are expected to be robust in terms of reliability in use-tests under variable temperature and moisture conditions, this means they should not experience package warpage or decreased performance.

As an example of today's best PoP technology, the bottom device may have a square-shaped substrate of 12 by 12 mm. On the substrate bottom surface are output terminals with 0.5 mm pitch and attached solder balls of 0.3 mm diameter. In the center of the substrate top surface is a semiconductor chip assembled onto the substrate by wire bonding. The thickness of the chip is in the range from about 0.1 to 0.25 mm; it may be as low as 0.05 mm. The squashed sphere and the arch of the bonding wire consume about 0.1 mm height over the chip. The chip plus surrounding keep-out zone (for the stitch-end of the bonding wire) are encapsulated by molding compound, which has a total thickness of 0.27 mm. A peripheral area up to the 12 by 12 mm outline is left for placing the terminal pads (capture pads) to connect to the inputs/outputs (I/O's) of the top package. Dependent on the size of the peripheral area, two or three rows of capture pads can be configured around the perimeter, resulting in a maximum capability for about 200 I/O's for the exemplary PoP. The pads have a pitch of 0.65 mm center-to-center.

The top device has, in matching locations, respective two or three rows of terminals at 0.65 mm pitch. Solder balls of 0.4 mm diameter are attached to the terminals. These solder balls are pressed to 0.32 mm height, when they are reflowed to assemble the top device onto the bottom device. The resulting standoff of 0.32 mm is sufficient to accommodate the 0.27 mm height of the molded encapsulation.

In general, for given substrate area minus the molded area, the pitch of terminals pads is determined by the number of I/O's. The pitch, in turn determines the size of affordable solder balls. Further, the height of the assembled solder balls determines the allowed height of the molded encapsulation.

In order to find an approach for PoP's to increase the number of I/O's while maintaining the area of the device, the industry is recently using a method for the bottom device to attach first conductive bumps to the top substrate surface terminals, and then to encapsulate the bumps together with the mounted chip in a molding compound. The bump height can be adjusted within a 0.010 to 0.015 mm range. Thereafter, blind vias are opened through the molding compound over the conductive bumps to reach and expose the top of the conductive material. The apertures of the vias are wide enough to accommodate the connecting solder bodies of the top package. For the stacking operation of the top package onto the bottom package, an automated placement machine equipped with a flux or solder paste dipping module positions the solder bodies of the top package inside the via apertures of the bottom package to make contact with the bumps in the vias. After reflowing the solder (at about 260° C.), a conductive connection is created from the bottom to the top device terminals.

### SUMMARY OF THE INVENTION

Applicant recognized that the market trends towards higher product performance as well as smaller product contours demand package-on-package (PoP) devices with higher numbers of I/O terminals, concurrent with stacked chips in the bottom devices. As a consequence, the market is driving towards pad pitches substantially finer than the present 0.65 mm, and simultaneously towards thicknesses of the bottom package greater than the present 0.27 mm.

Further, applicant discovered that, for the bottom packages, the method of opening windows into the molding compound to expose solder bumps creates rough, un-even via sidewalls at the bump interface so that in the subsequent solder reflow cycle thermomechanical stresses are created between sidewalls and solder, which may lead to disruptive microcracks in the metal fillings. In addition, the present assembly approach, based on compound molding as the first step and via opening as the second step, is time-consuming and thus incompatible with the market requirements of low fabrication cost and rapidly changing customer needs demanding short turn-around time.

Applicant solved the problem of creating conductive through-vias, which can address both the need for decreasing I/O pitches and for increasing package thicknesses with stacked chips, by reversing the present sequence of process steps: In the first step, the vias are created through the complete molded thickness, and in the second step, enough solder balls are filled into each via to insure contact with the solder body attached to the top package. For through-vias formed approximately as inverted truncated cones, the filler-solder balls may have a smaller diameter than the attached solder body. In the example, quoted above, of a PoP with a 12×12 mm substrate of the bottom device, the process of the invention allows to increase the number of I/O's from 200 to 288 with a terminal pitch of only 0.4 mm, while the bottom package may now contain two, three, or more stacked chips. The new process is specifically advantageous for filling through-vias with an aperture diameter less than 75% of the depth—a configuration especially suited for shrinking the I/O pitch while concurrently increasing the package thickness.

Applicant further selected the method of fabricating the through-vias so that smooth via sidewalls are created. In one technique, the through-vias are formed during the molding process by using a mold cover with truncated cone-shaped protrusions in the locations matching the via locations. Due to the smooth mold steel, the via-hole sidewalls are inherently smooth. Alternatively, the through-vias may be created by lasers, which create inverted truncated cone-shaped openings with smooth sidewalls.

Next, the bottom of each through-via is prefluxed. Then, a dispensing equipment places at least 2 solder balls of a diameter not more than the truncation diameter into each through-via. During the PoP assembly, the incoming solder body attached to the top PoP package fills the remainder of each through-via with solder. Due to the smooth via sidewalls, no stress is created by the solder reflow temperature excursion.

It is a technical advantage of the invention that the fabrication method of the PoP bottom device, including the step of encapsulating the top side in molding compound, proceeds in wafer form; the singulation into discrete devices by sawing is the last process step. As a result, the molding step provides each discrete device with a maximum amount of the robust molding material, contributing significantly to minimize any device warpage during the temperature excursion for assembling the PoP.

It is another technical advantage of the invention that the process step of opening the vias for exposing the device terminals proceeds through the whole thickness of the molded material and further creates smooth via sidewalls. As a result, the formation of any sidewall protrusions, un-evenness, or rough-spots, is avoided, which otherwise may act as concentration points for thermomechanical stress during the temperature excursion for assembling the PoP.

Yet another technical advantage of the invention is the high production throughput, when all through-vias are formed concurrently in a mold, which uses a cover provided with an insert of steel protrusions in the locations of the vias.

In yet another technical advantage of the invention, the overmolded bottom device may include one or more wire-bonded chips, giving the PoP the advantage of using existing chips for increased performance.

Yet another advantage of the invention is a minimized warpage of the PoP due to method of molding whole wafers and singulating discrete devices after molding.

### BRIEF DESCRIPTION OF THE DRAWINGS

FIG. 1 illustrates a schematic cross section of a package-on-package (PoP) device fabricated by the method of the invention, exhibiting via holes with straight sidewalls and an opening diameter less than 75% of the via height.

FIGS. 2 to 8 are schematic cross sections illustrating process steps to fabricate the PoP device of FIG. 1.

FIG. 2 is a schematic cross section of a substrate strip with a plurality of packaged first devices after opening the via holes through the complete package thickness.

FIG. 3 shows a schematic cross section of the substrate strip of FIG. 2 after the step of cleaning the via holes.

FIG. 4 depicts the process step of distributing flux into the via holes.

FIG. 5A illustrates the process step of depositing the first solder ball into each via to pre-fill the vias.

FIG. 5B shows the substrate strip after pre-filling the vias with more than one solder ball.

FIG. 6 shows the substrate strip after the process step of reflowing the pre-filled solder in the vias.

FIG. 7 depicts the substrate strip after attaching the solder bodies for connecting to external parts and before the step of singulating discrete first devices.

FIG. 8 is a schematic cross section of the process step of assembling a first and a second device to create a PoP.

### DETAILED DESCRIPTION OF THE PREFERRED EMBODIMENTS

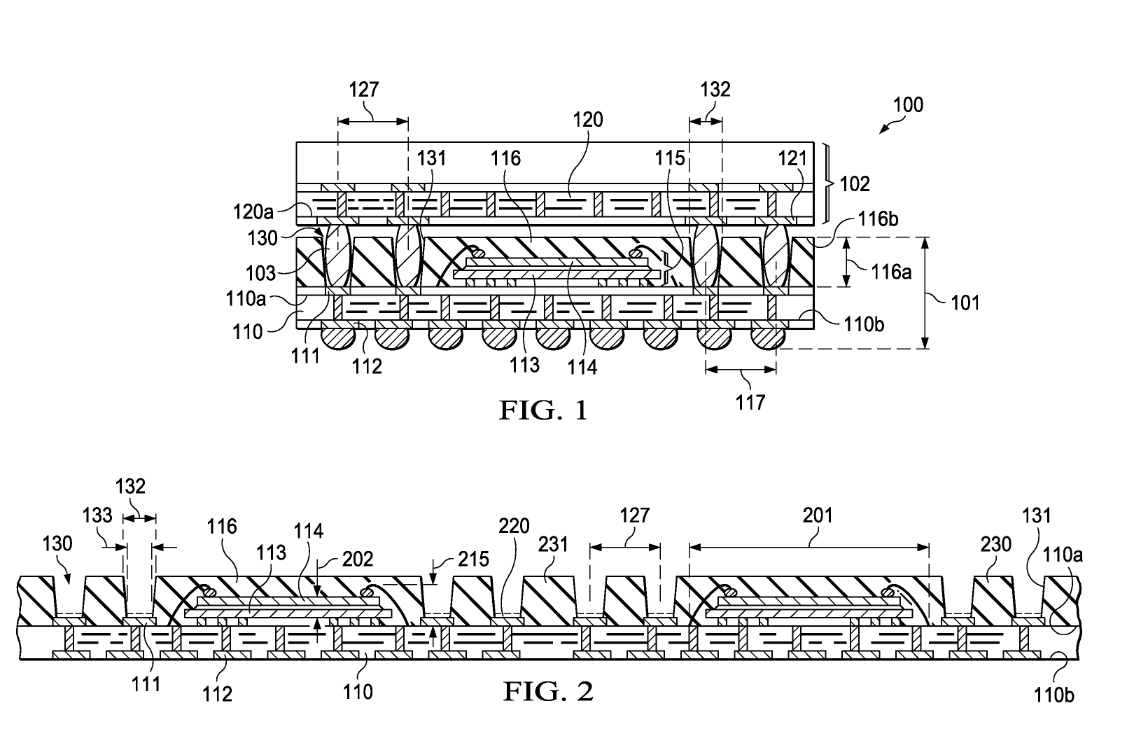

FIG. 1 illustrates an exemplary package-on-package (PoP) device, generally designated 100, according to an embodiment of the invention. PoP device 100 includes a first packaged device 101, a second packaged device 102, and solder bodies 103 connecting devices 101 and 102 electrically and mechanically.

First device 101 includes a first substrate 110, which is made of an insulating material yet integral with conductive lines and vias. First substrate 110 has a first side 110a and a second side 110b. On first side 110a are first contact pads 111, and on second side 110b are second contact pads 112. Second device 102 includes a second substrate 120, which is made of an insulating material yet integral with conductive lines and vias. Second substrate 120 has a third side 120a, which is oriented to face first device 101. On third side 120a are third contact pads 121.

In the area of substrate 110 is divided into a region, preferably in the approximate center of the of the substrate area, which is reserved for assembling semiconductor chips. In the example of FIG. 1, the central region shows a stack 115 of two chips assembled: one chip 113 has metal bumps for flip-attaching chip 113 to the substrate 110; the other chip 114 is adhesively attached to chip 113 and wire-bonded to substrate 110. In other devices, there may be stacks of three or more chips, or stacks of multi-chips assembled adjacent to each other. The chips may be flip-assembled or wire bonded in any combination. Each chip has a thickness, preferably ranging from about 100 to 250 μm; within a stack of chips, the thickness of the chips may be equal or different. Distributed in the area of the substrate periphery are first contact pads 111 on the first substrate side 110a. Neighboring first contact pads have a pitch 117 center-to-center.

As FIG. 1 shows, the first substrate side 110a, including the chip stack 115, is encapsulated in a compound 116, forming a first package with a height 116a. A preferred compound is an epoxy-based molding compound because molding materials together with the molding technique and controls are well established. The top surface 116b of the compound is the top surface of first device 101. FIG. 1 illustrates the fact that first package height 116a will increase with the number and thickness of the stacked chips and the arch of the bonding wires used for chip assembly.

FIG. 1 shows a plurality of via holes 130 in the encapsulation compound, extending from the top package surface 116b through the package height 116a to a respective first contact pad 111. For brevity, the via holes or through vias 130 are frequently simply referred to as vias. As FIG. 1 indicates, the vias have substantially straight, smooth sidewalls 131. Furthermore, the vias have a diameter 132 at the top surface 116b; as discussed below, diameter 132 is less than 75% of the height 116a. As FIG. 1 further indicates, the vias are preferably shaped as approximate inverted truncated cones; consequently, the via diameter 133 at the pad 111 is smaller than the top diameter 132. This shape is a consequence of the method used to open the vias (see below). Alternatively, the vias may be shaped as approximate cylinders with sidewalls parallel to each other; in this case the via diameter at the interface with pad 11 is the same as the top diameter 132.

As stated above, the exemplary PoP device of FIG. 1 further has the second package 102, which includes the second substrate 120. The third side 120a of substrate 120 faces the top surface 116b of first package 101. The third contact pads 121 on the third side 120a have a pitch 127 center-to-center, which is identical to the pitch 117 of the first contact pads. Consequently, third pads 121 can be aligned, or be in line, with the first pads 111 on the first side 110a of the substrate 110 of the first device 101.

FIG. 1 illustrates that, based on the alignment of third pads 121 with first pads 111, solder bodies 103, which fill the vias 130, can electrically connect the third pads 121 with the respective first pads 111 to form the PoP device. The process of filling vias 130 with solder bodies 103 is described below. As FIG. 1 indicates, solder bodies 103 should preferably end up slightly higher than via height 116a; this difference of height keeps the top surface 116b of the first device 101 from touching the third surface 120a of the second device 102.

Another embodiment of the invention is a method for fabricating a PoP while satisfying two concurrent trends: Allow the pitch of the contact pads and thus the top diameter of the via to decrease, and allow the height of the assembled chip stack and thus the encapsulating compound and the height of the via to increase.

In actual manufacturing, the via holes will have a shape resembling an inverted truncated cone; an optimum borderline case would be a via hole resembling a cylinder. Let the height of the cylinder be h and its diameter be d. The volume V_{c} of the via cylinder is thus V_{c}=¼d² h π. In order to fill this via volume with solder, the second device contributes at most the volume of a solder ball, which fits into the via opening of diameter d at the top surface; this solder ball has the volume Vₛ of a sphere with diameter d; Vₛ=⅙ d³ π. Since the cylinder has the same diameter on the bottom as on the top, the balance of the via volume is filled by a second sphere of diameter d. The height of a cylinder-shaped via having a volume equal to 2 times ⅙ d³ π is given by h=4/3 d. Considering the diameter of the cylinder-shaped via as a function of the via height, d=¾ h=0.75 h. The via diameter 132 in FIG. 1 at the top surface is 75% of the via height 116a.

When vias are shaped more realistically as inverted truncated cones rather than cylinders, the second solder sphere has to have a smaller diameter than d. Consequently, when height h is fixed, the large-diameter solder sphere of the second device cannot touch the small-diameter solder sphere at the bottom of the via; the spheres thus cannot be unified after melting. The dilemma is aggravated, when h concurrently has to increase because of the stacking and wire bonding of chips, while d has to decrease because of shrinking pad pitch. Consequently, the PoP product trend requires a capability to fill solder into vias with d<0.75 h or even d<<0.75 h. This requirement is best fulfilled by loading more than one solder ball into each cone-shaped via hole of the first device before the second device is joined with the first device to create the PoP. For cone-shaped vias with narrow end at the contact pad of the first device, the diameter of the pre-loaded solder balls is preferably the diameter of the narrow end of the cone; these solder balls are thus smaller than the solder ball attached to the contact pad of the second device. A sequence of a number of process steps is depicted in FIGS. 2 to 8.

FIG. 2 illustrates a portion of a strip of an insulating substrate 110 (the conductive lines and vias integral with the substrate are not shown in FIG. 2). Substrate 110 has a first side 110a and a second side 110b. On the first side 110a are contact pads 111 with a pitch 127 center-to-center of neighboring pads; on the second side 110b are contact pads 112. On the first side 110a are locations for assembling stacks of semiconductor chips.

As an example, FIG. 2 illustrates a portion of a substrate 110 with a couple of locations 201, where a stack 202 of two chips has been assembled; in other examples, there may be a stack of three or more chips, or there may be adjacent stacks of multi-chips. One of the chips 113 has metal bumps to be flip-contacted onto substrate surface 110a, the other chip 114 is attached to the first chip and wire bonded to surface 110a. The chip stack, the wire ball diameter and the arch of the bonding wires result in a height 215, which is the minimum height the intended encapsulation has to have to protect the assembled chips. A reliable process window should preferably allow 50 μm of encapsulation compound on top of the wire arch. Chip thicknesses range from about 100 to 250 μm; wire ball diameters are typically 1.6 times the wire thickness (between 15 and 25 μm); the wire arches are preferably at least as high as the heat-affected wire zone caused by the temperature of the ball formation process (between about 30 and 50 μm).

In the next process step, the first substrate side 110a is encapsulated in an insulating compound. Preferably, a molding technique is used and the compound is an epoxy-based molding compound with inorganic fillers for mechanical strength and reducing the compound coefficient of thermal expansion. The goals of the encapsulation step are to protect the assembled chips and confer mechanical strength to substrate 110, while allowing access to the contact pads 111. The preferred encapsulation methods include a molding process using a cavity mold with one part designed to have protrusions for keeping pads 111 open, and a molding process creating a general overmold followed by a step of removing compound portions for opening the access to the pads. In either method, the resulting openings to the pads are via holes through the complete molded thickness with straight sidewalls.

In the method of using a mold with a specially designed part, a mold made of steel or another suitable material is provided, which allows the encapsulation of a substrate strip with an assembled array of devices. The mold has a top portion and a bottom portion; the top portion is manufactured to leave open the cavities for accessing the contact pads 111 on the first substrate surface 110a. The top portion includes protrusions and recesses; the bottom portion is without corresponding protrusions. The protrusions of the top portion are at locations matching the pad locations 111. The protrusions are preferably shaped as truncated cones of a height, with the cone surface angled within a preferred range from about 5 to 20 degrees from vertical. The diameter of the base of the cone, where it is protruding form the steel of the top mold portion, is less than 75% of the cone height. Furthermore, the protrusions preferably may have a ridge, which may extend along the whole angled side of the cone. The ridge is operable to create a groove or channel in the molded part, which may provide release of gas in the solder ball attachment process, or help in the solder paste reflow process.

The height of the protrusion is selected to be suitable to approach the substrate pad metal 111 in the closed mold. Preferably, the protrusion should approach the pad metal surface in the closed mold to a distance between 0 and about 50 μm. More preferably, the height of the protrusion is sufficient to touch the surface of the pad metal 111 in the closed mold.

The substrate 110 with the assembled chips 202 is loaded onto the featureless bottom mold portion. The second substrate surface 110b is rested on the bottom mold portion, and the first substrate surface 110a with the contact pads 111 is positioned away from the bottom mold portion. The protrusions of the top mold portion are aligned with the respective contact pads 111.

After closing the mold by clamping the top portion onto the bottom portion, the cavities of the mold for holding the semiconductor chips are formed. The protrusions are aligned with the contact pads 111, approaching or touching the pad surface; material or alignment tolerances may cause a residual distance between 0 and about 20 μm between the protrusion and the respective pad. In FIG. 2, such potential residual material 220 is indicated by dashed contours.

Next, encapsulation material such as epoxy-based and filler-loaded molding compound is pressured into the cavities to fill the cavities. By this transfer molding step, encapsulations 131 for the devices of the array are created, as well as the separations 230 and 231. After partially polymerizing the compound, the mold is opened and the substrate together with the encapsulated array of chips is removed from the mold. Subsequently, the compound is fully polymerized. As the cross section of FIG. 2 shows, the via holes 130 in the encapsulation to the pad locations have straight smooth sidewalls 131, as necessitated by the straight smooth surfaces of the steel protrusions of the mold. The via holes 130 have the shape of inverted truncated cones, where the diameter 133 of the inverted cone is smaller than the diameter 132 of the via at the aperture.

Alternatively, the cavity direct injection molding technique or the liquid compression molding technique may be employed. These techniques use a plastic film held to the top mold portion by vacuum suction, resulting in straight smooth sidewalls of the vias.

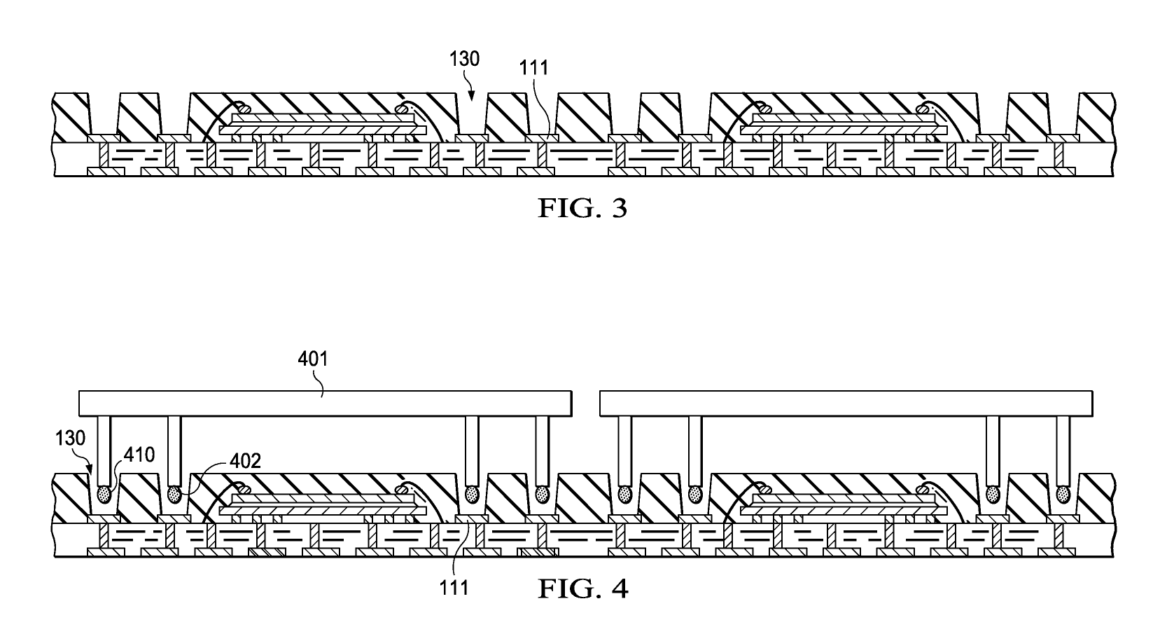

FIG. 2 indicates by dashed contour 220 any residual encapsulation formed on the contact pads 111. These thin deposits (thickness between 0 and about 20 μm) have to be removed to expose the clean metal surface of pad 111. At least three methods are suitable to remove these unwanted encapsulation layers. The first method employs drilling or vaporizing by laser light. A focused laser beam shines into the via holes 130 and removes the compound layer. The second method employs a plasma clean-up process. The third method employs a chemical etch process. All three methods are material-sensitive and thus controllable to stop at the metal surface of the contact pads. FIG. 3 illustrates the cleaned via holes 130, exposing the clean metal surface of pads 111.

In an alternate method for opening the via holes, the first substrate surface 110s with the assembled chip stacks 202 is overmolded uniformly in a compound thickness suitable for the height of the stacks and the bonding wire arches. Thereafter, laser beams are used to open via holes 130 through the compound thickness to expose contact pads 111, creating vias with an approximate inverted truncated cone shape and straight smooth sidewalls, as shown in FIG. 3.

In the next process step displayed in FIG. 4, a droplet 410 of chemical flux is distributed onto the surface of metal pad 111 in each via hole 130. FIG. 4 depicts schematically a tool 401 with a plurality of nozzles 402 to dispose these droplets simultaneously in a plurality of via holes 130.

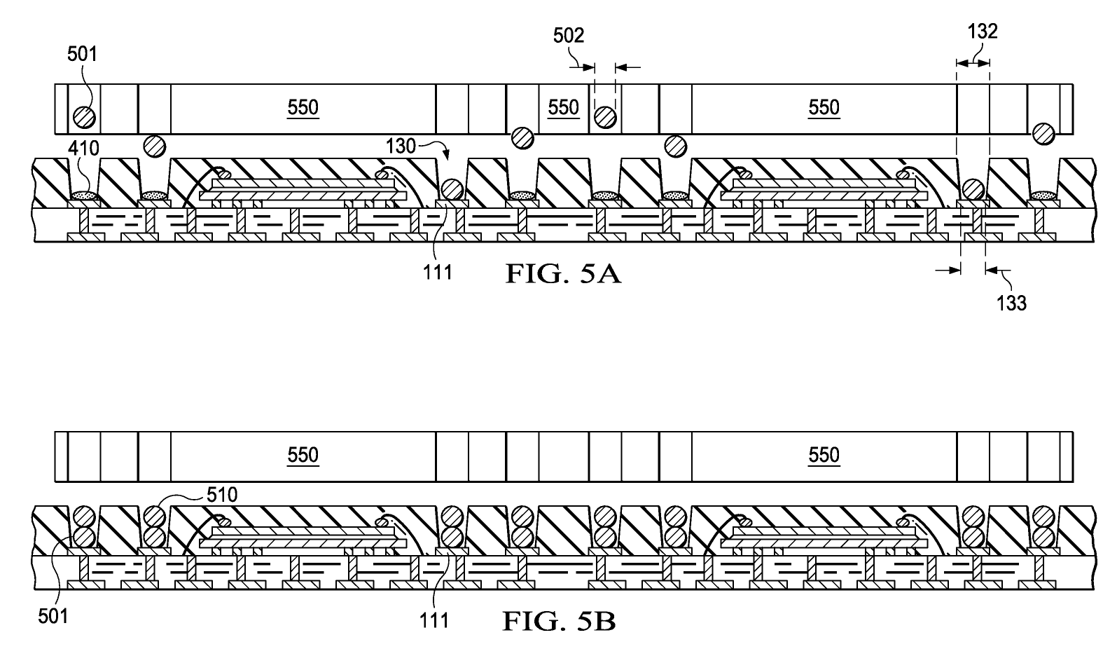

FIG. 5A illustrates the flux droplets 410 on the surface of metal pads 111 in each via hole 130 at the time, when in the next process step the first solder ball 501 is dropped into each via hole 130. The apparatus 550 used for distributing the solder balls is a sieve with openings sized to drop one ball at a time (apparatus 550 is sketched only schematically in FIG. 5). The diameter 502 of solder balls 501 is such that the ball establishes contact at least with flux deposit 410, preferably with the surface of metal pad 111. Consequently, ball diameter 501 has about the size of the via diameter 133 at the truncated end of the inverted cone, which is smaller than the via diameter 132 at the aperture.

As discussed above, for most devices a second solder ball 510 of the same size as ball 501 is needed to fill the volume of via 130 high enough with solder so that during the PoP assembly contact can be established between the solder in the vias and the respective solder body of the second device. FIG. 5B depicts the vias after the second solder ball 510 has been dropped into each via.

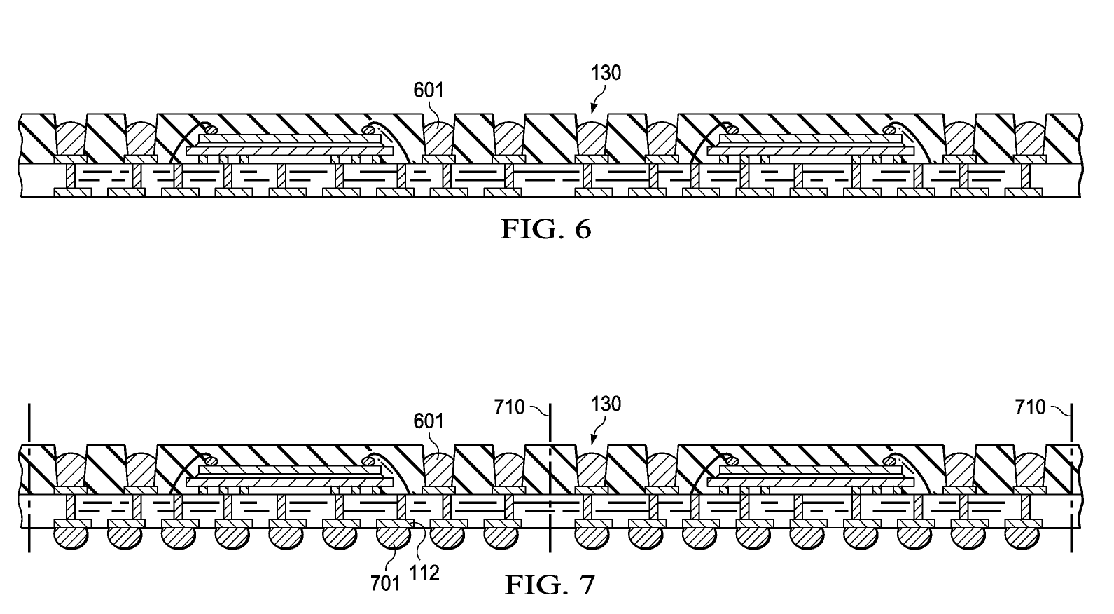

In the next process step, the temperature is raised to reflow the solder balls 501 and 510 while wetting the respective first pads 111. The resulting solder filling of vias 130 is designated 601 in FIG. 6. It is preferred that the height of the reflowed solder filling is at least equal to the via diameter (133 in FIG. 2) at the pad 111, more preferably greater than the via diameter.

Referring now to FIG. 7, in the next process step solder balls 701 are attached to the second contact pads 112 of substrate 110. Solder balls 701 serve the connection to external parts. Solder balls 701 may have a size different from the size of solder balls 501; they may also be made of a different alloy having a different reflow temperature. FIG. 7 also indicated the cut lines 710 for singulating the strip-size first device into discrete units 101.

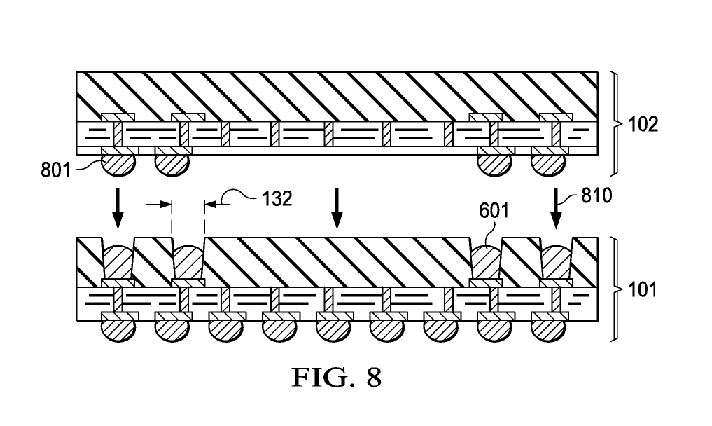

FIG. 8 illustrates a discrete first packaged device 101 and a discrete second packaged device 102 in the process step of being jointly assembled to form a PoP device. The solder bodies 801 attached to the second packaged device 102 are aligned with the respective via openings 132 of the first packaged device 101. The diameter of attached ball 801 is sized to fit into via opening 132. By moving second device 102 as indicated by arrows 810, solder bodies 801 of the second device 102 are brought in contact with the reflowed solder 601 in the respective vias of first device 101. The temperature is raised to reflow and unite the solders 801 and 601 in each via, thereby forming a PoP apparatus. The resulting PoP device is designated 100 in FIG. 1.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type and any number of semiconductor chips, discrete or integrated circuits; it further applies to combinations of active and passive components, and to any material of the semiconductor chips including silicon, silicon germanium, gallium arsenide, or any other semiconductor or compound material used in semiconductor manufacturing.

As another example, the via holes may be shaped as cylinders or as inverted truncated cones. There may be none, one, or two, or more drops of flux before the pre-filling of the via holes with solder balls. The via holes may have to be pre-filled with two, three or more solder balls. There may be an additional clean-up step after the reflow step for combining the solder in the via holes.

It is therefore intended that the appended claims encompass any such modifications or embodiment.

I claim:

1. An apparatus comprising:
a first packaged device electrically connected to a second device by at least two oblong solder bodies;
each solder body extending inside a via hole extending through the package thickness of the first device, the vias having an aperture diameter and a depth; and
the via aperture diameter being less than 75% of the via hole depth.

2. The apparatus of claim 1 wherein the via holes further include straight sidewalls.

3. The apparatus of claim 2 wherein the vias are shaped as inverted truncated cones.

4. The apparatus of claim 1 wherein the first packaged device includes a stack of at least two semiconductor chips assembled inside the package.

5. The apparatus of claim 4 further including wire bonds for the assembly of at least one of the at least two chips in the stack.

6. The apparatus of claim 1 wherein the at least two solder bodies have a pitch center-to-center.

7. An apparatus comprising:
a first device including:
a first substrate having a first and a second side;
a stack of at least two semiconductor chips on the first substrate side;
first contact pads on the first substrate side;
the first substrate side, including the chip stack, being in a first package having a height and a top surface; and
via holes extending from the top package surface through the package height to the first contact pads, the via holes having straight sidewalls and a diameter at the top surface of less than 75% of the height;
a second package including:
a second substrate having a third side facing the top surface of the first package; and
third contact pads on the third side, the third pads being in line with the first pads; and
solder bodies filling the via holes and connecting the third pads with the respective first pads.

8. The apparatus of claim 7 wherein at least one of the at least two chips of the first device is wire bonded to the first substrate side.

9. The apparatus of claim 7 wherein the vias are shaped as inverted truncated cones.

10. The apparatus of claim 7 wherein neighboring first contact pads have a pitch center-to-center.

11. The apparatus of claim 7 wherein the first substrate further includes a perimeter.

12. The apparatus of claim 11 wherein the first contact pads are configured around the perimeter of the substrate.

13. The apparatus of claim 7 wherein the second side of the first substrate has second contact pads including attached solder balls to connect to external parts.

14. An apparatus comprising:
a substrate having a first and a second side;
a stack of at least two semiconductor chips on the first substrate side;
first contact pads on the first substrate side;
the first substrate side, including the chip stack, being in a package having a height and a top surface; and
via holes extending from the top package surface through the package height to the contact pads, the via holes having straight sidewalls and a diameter at the top surface of less than 75% of the height; and
solder bodies filling the vias from the contact pads to a level at least as high above the contact pads as the via diameter at the contact pads.

15. The apparatus of claim 14, wherein at least one of the at least two chips of the first device is wire bonded to the first substrate side.

16. The apparatus of claim 14 wherein the vias are shaped as inverted truncated cones.

17. The apparatus of claim 14, wherein the second side of the substrate has second contact pads including attached solder balls to connect to external parts.

18. A method for fabricating an apparatus comprising the steps of:
assembling stacks of at least two semiconductor chips on the first side of a substrate strip having first contact pads on the first side and second contact pads on the second side;
encapsulating the first substrate side, including the first contact pads and the assembled stacks, in a compound of a height;
forming via holes through the height of the encapsulation compound to expose the first contact pads so that the vias have straight sidewalls and an opening diameter of less than 75% of the height;
depositing at least one solder ball into each via hole to contact the respective first pad;
raising the temperature to reflow the solder balls and wet the respective first pads, thereby completing the fabrication of first packaged devices;
aligning the solder bodies attached to a second packaged device with the respective via openings of a first packaged device;
bringing the solder bodies of the second device in contact with the reflowed solder in the respective vias of the first device; and
raising the temperature to reflow and unite the solders in each via, thereby forming a package-on-package (PoP) apparatus.

19. The method of claim 18 further including, after the step of forming via holes, the step of removing any remaining flash of encapsulation compound.

20. The method of claim 19 further including, after the step of removing, the step of applying flux in each via hole.

21. The method of claim 18 further including, after the step of depositing a first solder ball, the step of depositing a second solder ball into each via hole.

22. The method of claim 18 wherein the step of forming via holes is performed as a concurrent part of the step of encapsulating by using an encapsulation apparatus having a part including protrusions and recesses, wherein the protrusions are at locations matching the first contact pad locations and shaped as truncated cones of a height suitable to approach the pad metal surface ion the closed apparatus.

23. The method of claim 18 wherein the step of forming via holes is performed by a laser technique opening the vias into the encapsulation compound.

24. The method of claim 18 further including the step of singulating the strip-size first devices into discrete units.
